(19) United States
(12) Patent Application Publication
(10) Pub. No.: US 2015/0325729 A1
(43) Pub. Date: Nov. 12, 2015

(54) ENCAPSULANT COMPOSITION COMPRISING A COPOLYMER OF ETHYLENE, VINYL ACETATE AND A THIRD COMONOMER

(71) Applicant: E. I. DU PONT DE NEMOURS AND COMPANY, Wilmington, DE (US)

(72) Inventor: JANE KAPUR, Kennett Square, PA (US)

(21) Appl. No.: 14/703,909

(22) Filed: May 5, 2015

Related U.S. Application Data
(60) Provisional application No. 61/990,788, filed on May 9, 2014.

(51) Int. Cl. H01L 31/048

(52) U.S. Cl. CPC H01L 31/0481

(57) ABSTRACT

Provided herein is an encapsulant composition. The encapsulant composition, which is useful in photovoltaic modules, comprises a copolymer of ethylene, vinyl acetate and a third comonomer. Preferred third comonomers include methacrylic acid, carbon monoxide, acrylic acid, maleic anhydride mono-methyl ester (MAME), and maleic anhydride. Further provided herein is a photovoltaic module comprising the encapsulant composition. The photovoltaic module is less susceptible to potential-induced degradation than are photovoltaic modules that use conventional encapsulants that are primarily copolymers of ethylene and vinyl acetate.

### CROSS-REFERENCE TO RELATED APPLICATION

The present application claims priority under 35 U.S.C. §119 to U.S. Provisional Appln. No. 61/990,788, filed on May 9, 2014, which is incorporated herein by reference in its entirety.

### FIELD OF THE INVENTION

Provided herein is an encapsulant composition for a photovoltaic module. The encapsulant composition comprises a copolymer of ethylene, vinyl acetate and a third comonomer. Preferred third comonomers include methacrylic acid, carbon monoxide, acrylic acid, maleic anhydride mono-methyl ester (MAME), and maleic anhydride. Further provided herein is a photovoltaic module comprising the encapsulant composition. The photovoltaic module is less susceptible to potential-induced degradation than are photovoltaic modules that use encapsulants that are primarily copolymers of ethylene and vinyl acetate.

### BACKGROUND OF THE INVENTION

Several patents and publications are cited in this description in order to more fully describe the state of the art to which this invention pertains. The entire disclosure of each of these patents and publications is incorporated by reference herein.

Photovoltaic modules are an important source of renewable energy. In particular, they include solar cells that release electrons when exposed to sunlight. These solar cells, which are usually semiconductor materials that may be fragile, are typically encased or encapsulated in polymeric materials that protect them from physical shocks and scratches. The encased solar cells are generally further protected by glass or by another outer layer that is resistant to weathering, abrasion or other physical insults.

Ideally, the encapsulant, the glass layers and the other components in the photovoltaic module protect the solar cells and do not detract from the efficiency of the conversion of light to electricity. The phenomenon of potential-induced degradation (“PID”), however, is a known problem that causes solar cells to decrease or to cease producing electricity when a photovoltaic module operates with a large potential between its solar cells and another portion of the module, such as a frame, for example. Therefore, one approach to the problem of PID is to design modules in which the solar cells are electrically insulated from the frames and other portions of the module, thereby preventing the development of these large internal potentials or “polarization.” See, for example, U.S. Patent Appln. Publn. No. 20120266943, by Li. In another approach, U.S. Pat. No. 7,554,031, issued to Swanson et al., describes providing conductive pathways between various portions of the photovoltaic module, so that harmful polarization is minimized or prevented.

Several different factors are believed to contribute to PID. For example, in U.S. Patent Appln. Publn. No. 2011/0048505, by Bunea et al., it is asserted that PID can be reduced or eliminated by operating the solar cells under exposure to an increased proportion of solar UV irradiation. Without wishing to be held to theory, however, the migration of water and ions to the surface of the solar cells appears to be the major mechanism of PID. Other factors affecting PID, such as the voltage at which the photovoltaic modules are operated and the design of the electrical circuits, are believed to be secondary in that they affect the magnitude or direction of the water and ion migration.

In particular, it is hypothesized that the diffused water and ions cause a detrimental electrochemical reaction that deactivates the p-n junctions of the solar cells. In this connection, in Intl. Patent Appln. Publn. No. WO2013/020128 by Aitken et al., it is asserted that PID can be reduced or eliminated by substituting glass that is free of or substantially free of alkali ions, such as sodium ions, for standard soda-lime glass in photovoltaic modules. The importance of selecting a chemically appropriate anti-reflective coating has been discussed in S. Pingel et al., “Potential Induced Degradation of Solar Cells and Panels,” 35^{th} IEEE PVSC, Honolulu, 2010, 2817-2822, for example. The rate of PID can be controlled by varying the Si-to-N ratio which is a function of the refractive index and thus corresponds to optical characteristics. In addition, U.S. Pat. No. 8,188,363, issued to Xavier et al., asserts that PID can be eliminated by interposing an electrically insulating fluorocarbon layer between the glass and the solar cells. This fluorocarbon layer may also be a barrier to the migration of water or ions.

Furthermore, other important properties of photovoltaic modules are known to be affected adversely by elevated temperature and levels of moisture. These properties include, for example, mechanical integrity, electrical properties such as volume resistivity, current leakage, and overall cell efficiency.

Therefore, it is important to understand and control the factors that influence the rate and magnitude of moisture ingress and ion migration in encapsulants. An encapsulant that effectively prevents or reduces the movement of water and ions within a photovoltaic module will allow greater flexibility in the module's design and operating conditions. Moreover, this encapsulant will increase the module's efficiency and useful lifetime by reducing or preventing PID.

It is apparent from the foregoing that a need exists for polymeric materials that, when used as encapsulants in photovoltaic modules, prevent or reduce the potential-induced degradation of solar cells.

### SUMMARY OF THE INVENTION

Accordingly, provided herein is an encapsulant composition for a photovoltaic module. The encapsulant composition comprises a copolymer of ethylene, vinyl acetate and a third comonomer. Preferred third comonomers include methacrylic acid, carbon monoxide, maleic anhydride mono-methyl ester (MAME), acrylic acid, and maleic anhydride. Further provided herein is a photovoltaic module comprising the encapsulant composition. The photovoltaic module is less susceptible to potential-induced degradation than photovoltaic modules that use conventional encapsulant compositions, such as those that are primarily copolymers of ethylene and vinyl acetate.

### BRIEF DESCRIPTION OF THE FIGURES/DRAWINGS

FIG. 1 is a set of photographs showing electroluminescence images of a conventional photovoltaic module.

FIG. 2 is a set of photographs showing electroluminescence images of a photovoltaic module of the present invention.

### DETAILED DESCRIPTION

The following definitions are used herein to further define and describe the disclosure. These definitions apply to the terms as used throughout this specification, unless otherwise limited in specific instances.

Unless otherwise defined, all technical and scientific terms used herein have the same meaning as commonly understood by one of ordinary skill in the art to which this invention belongs. In case of conflict, the present specification, including the definitions set forth herein, will control.

Unless explicitly stated otherwise in defined circumstances, all percentages, parts, ratios, and like amounts used herein are defined by weight.

When materials, methods, or machinery are described herein with the term “known to those of skill in the art”, “conventional” or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The transitional phrase “consisting of” excludes any element, step, or ingredient not specified in the claim, closing the claim to the inclusion of materials other than those recited except for impurities ordinarily associated therewith. When the phrase “consists of” appears in a clause of the body of a claim, rather than immediately following the preamble, it limits only the element set forth in that clause; other elements are not excluded from the claim as a whole.

The transitional phrase “consisting essentially of” limits the scope of a claim to the specified materials or steps and those that do not materially affect the basic and novel characteristic(s) of the claimed invention. A ‘consisting essentially of’ claim occupies a middle ground between closed claims that are written in a ‘consisting of’ format and fully open claims that are drafted in a ‘comprising’ format. Optional additives as defined herein, at levels that are appropriate for such additives, and minor impurities are not excluded from a composition by the term “consisting essentially of”.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

Further in this connection, certain features of the invention which are, for clarity, described herein in the context of separate embodiments, may also be provided in combination in a single embodiment. Conversely, various features of the invention that are, for brevity, described in the context of a single embodiment, may also be provided separately or in any sub-combination.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

Further, unless expressly stated to the contrary, the conjunction “or” refers to an inclusive or and not to an exclusive or. For example, the condition “A or B” is satisfied by any one of the following: A is true (or present) and B is false (or not present), A is false (or not present) and B is true (or present), and both A and B are true (or present). Exclusive “or” is designated herein by terms such as “either A or B” and “one of A or B”, for example.

The term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. The scope of the invention is not limited to the specific values recited when defining a range.

The term “alkyl”, as used herein alone or in combined form, such as, for example, “alkyl group” or “alkoxy group”, refers to saturated hydrocarbon groups that have from 1 to 8 carbon atoms having one substituent and that may be branched or unbranched.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 18 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such. The term “copolymer” may refer to polymers that consist essentially of copolymerized units of two different monomers (a dipolymer), or that consist essentially of more than two different monomers (a terpolymer consisting essentially of three different comonomers, a tetrapolymer consisting essentially of four different comonomers, etc.).

The term “acid copolymer”, as used herein, refers to a polymer comprising copolymerized units of an α-olefin, an α,β-ethylenically unsaturated carboxylic acid or its anhydride, and optionally other suitable comonomer(s), such as vinyl acetate or an α,β-ethylenically unsaturated carboxylic acid ester.

The term “ionomer”, as used herein, refers to a polymer that is produced by partially or fully neutralizing an acid copolymer.

The term “laminate”, as used herein alone or in combined form, such as “laminated” or “lamination” for example, refers to a structure having at least two layers that are adhered or bonded firmly to each other, optionally using heat, vacuum or positive pressure. The layers may be adhered to each other directly or indirectly. In this context, the term “directly” means that there is no additional material, such as an interlayer, an encapsulant layer or an adhesive layer, between the two layers, and the term “indirectly” means that there is additional material between the two layers.

Provided herein is an encapsulant composition. The encapsulant composition is useful in photovoltaic modules, for example. The encapsulant composition comprises a copolymer of ethylene, vinyl acetate, and a third comonomer. As used herein, the term “X” refers to the third comonomer; thus, the formula of the copolymer of ethylene, vinyl acetate, and the third comonomer is abbreviated as “E/VA/X”.

The amount of copolymerized residues of the third comonomer, X, in the E/VA/X copolymer ranges from preferably 0.1 to 10 wt %, more preferably 0.1 to 5 wt % and still more preferably 0.1 to 2 wt %, based on the total weight of the E/VA/X copolymer.

The amount of copolymerized residues of vinyl acetate in the E/VA/X copolymer preferably ranges from 15 to 35 wt %, more preferably 20 to 34 wt %, and still more preferably 24 to 33 wt %, based on the total weight of the E/VA/X copolymer.

The amount of copolymerized residues of ethylene in the E/VA/X copolymer is complementary to the amounts of copolymerized vinyl acetate and third comonomer. Stated alternatively, 100 wt % is the sum of the weight percentages of the comonomer residues in the E/VA/X copolymer.

Suitable third comonomers for use in the E/VA/X copolymer include any comonomer capable of copolymerizing with ethylene and vinyl acetate. Examples of suitable third comonomers include, without limitation, α,β-ethylenically unsaturated mono- and di-carboxylic acids, esters of α,β-ethylenically unsaturated mono- and di-carboxylic acids, carbon monoxide, and maleic anhydride. Preferred third comonomers include α,β-ethylenically unsaturated carboxylic acids having from 3 to 8 carbon atoms, alkyl esters of α,β-ethylenically unsaturated carboxylic acids having from 3 to 8 carbon atoms, and maleic anhydride. More preferred third comonomers include acrylic acid, methacrylic acid, alkyl esters of acrylic acid and methacrylic acid.

Additionally, when X is an acid or an acid anhydride, the E/VA/X copolymer may be an ionomer. To obtain the ionomer of the E/VA/X copolymer, the E/VA/X copolymer is neutralized with a base so that the carboxylic acid groups or carboxylic acid anhydride groups in the E/VA/X copolymer react to form carboxylate groups. Preferably, the carboxylic acid groups or carboxylic acid anhydride groups in the E/VA/X copolymer are neutralized to a level of about 1 to about 90%, or about 5% to about 80%, or about 10% to about 70%, or about 15% to about 60%, or about 20% to about 50%, or up to about 20%, or up to about 17%, or up to about 15%, based on the total carboxylic acid or anhydride content of the E/VA/X copolymer as calculated or measured for the non-neutralized E/VA/X copolymers.

Any stable cation and any combination of two or more stable cations are believed to be suitable as counterions to the carboxylate groups in the ionomer. Divalent and monovalent cations, such as cations of alkali metals, alkaline earth metals, and some transition metals, are preferred. Zinc cations are preferred divalent ions, and sodium cations are preferred monovalent ions. In one embodiment, the base is a sodium ion-containing base, to provide a sodium ionomer wherein about 1% to about 50% or about 5% to about 30%, or about 10% to about 20% of the hydrogen atoms of the carboxylic acid groups of the precursor acid are replaced by sodium cations. In another embodiment, the base is a zinc ion-containing base, to provide a zinc ionomer wherein about 1% to about 50% or about 5% to about 30%, or about 10% to about 20% of the hydrogen atoms of the carboxylic acid groups of the precursor acid are replaced by a charge-equivalent quantity of zinc cations.

The E/VA/X copolymer resins may be neutralized by any conventional procedure, such as those disclosed in U.S. Pat. Nos. 3,404,134 and 6,518,365, and by other procedures that will be apparent to those of ordinary skill in the art. Some of these methods are described in detail in U.S. Pat. No. 8,334,033, issued to Hausmann et al.

Additionally, other comonomers (e.g., fourth or fifth comonomers) can be included in the copolymer of ethylene, vinyl acetate and third comonomer. These copolymers may be described more specifically as E/VA/X/Y or E/VA/X/Y/Z copolymers. When this is the case, the comonomers Y and Z are preferably selected from the same group as X, above. The amount of third, fourth and fifth comonomer(s), for example, is such that their combined weight percentages are in ranges of preferably 0.1 to 10 wt %, more preferably 0.1 to 5 wt %, and still more preferably 0.1 to 2 wt %, based on the total weight of the copolymer. In a non-limiting example, the E/VA/X/Y copolymer may include a combination of methacrylic acid and acrylic acid, or a combination of methacrylic acid and maleic anhydride. For convenience, however, the copolymers of ethylene, vinyl acetate and third comonomer are referred to herein generically in abbreviated form as the “E/VA/X copolymer”, even though the copolymers may include fourth, fifth or sixth comonomer(s), for example.

Suitable E/VA/X copolymers have physical properties that are fit for use in the encapsulant composition. In particular, the encapsulant composition desirably has an appropriate toughness and resilience, to cushion the solar cells and other electrical components of the photovoltaic module from physical shock. Also desirably, the encapsulant composition is easily processible, for example, capable of formation into sheets and capable of lamination under standard conditions. Further desirably, the encapsulant composition has suitable optical properties, such as transparency to solar radiation when used on the light-incident side of a photovoltaic module.

Accordingly, the physical properties of suitable E/VA/X copolymers include, without limitation, a melt index in the preferred range of about 0.5 to 500 g/10 min, more preferred range of about 1 to 200 g/10 min, and still more preferred range of 3 to 50 g/10 min, as measured by ASTM D1238-13, at 190° C. with 2.16 kg.

The E/VA/X copolymers may be synthesized by any suitable process, such for example as those described for grafted maleic anhydride terpolymers in U.S. Pat. No. 5,053,457, issued to I. Lee. In addition, suitable E/VA/X copolymers may be obtained from E.I. du Pont de Nemours and Company, Inc. (“DuPont”) of Wilmington, Del., under the trademarks Elvax® and Elvaloy®.

The encapsulant composition described herein may also include one or more other polymers. Preferably, these polymers form a blend with the E/VA/X copolymer and the other components of the encapsulant composition. Suitable other polymers include, without limitation, copolymers of ethylene and vinyl acetate (EVA), including the E/VA/X copolymers described herein, polyolefins, copolymers of ethylene and α,β-ethylenically unsaturated mono- and di-carboxylic acids, ionomers of copolymers of ethylene and α,β-ethylenically unsaturated mono- and di-carboxylic acids, and copolymers of ethylene alkyl esters of α,β-ethylenically unsaturated mono- and di-carboxylic acids. Preferred other polymers include, without limitation, copolymers of ethylene and vinyl acetate (EVA), copolymers of ethylene and methyl acrylate (E/MA), copolymers of ethylene and butyl acrylate (E/BA), terpolymers of ethylene and methyl acrylate or butyl acrylate with an α,β-ethylenically unsaturated mono- or di-carboxylic acid, ionomers of these acid terpolymers, and ionomers of E/VA/X copolymers. More preferred other polymers include, without limitation, copolymers of ethylene and vinyl acetate (EVA).

The amount of the one or more other polymers in the encapsulant composition ranges from preferably 0 to 98 wt %, more preferably 0 to 95 wt %, and still more preferably 0 to 90 wt %. Complementarily, the encapsulant composition preferably comprises preferably 2 to 100 wt % of the E/VA/X copolymer, more preferably 5 to 100 wt % of the E/VA/X copolymer, and still more preferably 10 to 100 wt % of the E/VA/X copolymer. The amounts of the copolymer and of the one or more other polymers are based on the total weight of the copolymer and of the one or more other polymers in the encapsulant composition.

The encapsulant composition may also contain additives for effecting and controlling cross-linking, such as organic peroxides, inhibitors and initiators. Suitable examples of cross-linking additives and levels of these additives are set forth in detail in U.S. Pat. No. 6,093,757, issued to F.-J. Pern, in U.S. Patent Publication Nos. 2012/0168982, by J. W. Cho et al., and 2012/0301991, by S. Devisme et al., and in Holley, W. W., and Agro, S. C. “Advanced EVA-Based Encapsulants—Final Report January 1993-June 1997”, NREL/SR-520-25296, Sep. 1998, Appendix D.

In addition, four particularly useful additives for use in the encapsulant compositions are thermal stabilizers, UV absorbers, hindered amine light stabilizers (HALS), and silane coupling agents. Suitable examples of the four additives and levels of these additives are set forth in detail in U.S. Pat. No. 8,399,096, issued to Hausmann, et al.

The encapsulant composition may also include one or more other additives. Suitable other additives may include, but are not limited to, plasticizers, processing aides, flow enhancing additives, lubricants, pigments, dyes, flame retardants, impact modifiers, nucleating agents, anti-blocking agents (e.g., silica), dispersants, surfactants, chelating agents, coupling agents, adhesives, primers, reinforcement additives (e.g., glass fiber), other fillers, and the like. Suitable other additives, additive levels, and methods of incorporating the additives into the copolymer compositions may be found in the Kirk-Othmer Encyclopedia of Chemical Technology, 5th Edition, John Wiley & Sons (New Jersey, 2004). In general, the total amount of these other additives, if present, is less than 5 wt %, less than 3 wt %, less than 2 wt %, or less than 1 wt %, based on the total weight of the encapsulant composition.

The encapsulant composition may be made by any suitable process, such as melt mixing. High-shear melt-mixing is preferred. Suitable high shear mixing equipment includes static mixers, rubber mills, Brabender mixers, Buss kneaders, single screw extruders, twin screw extruders, heated or unheated two-roll mills, and the like. Additional examples of suitable compounding processes and conditions may also be found in the Kirk-Othmer Encyclopedia and the Modern Plastics Encyclopedia, McGraw-Hill (New York, 1995).

The encapsulant composition may be formed into films or sheets by any suitable process. Information about these processes may be found in reference texts such as, for example, the Kirk Othmer Encyclopedia, the Modern Plastics Encyclopedia or the Wiley Encyclopedia of Packaging Technology, 2d edition, A. L. Brody and K. S. Marsh, Eds., Wiley-Interscience (Hoboken, 1997). For example, the sheets may be formed through dipcoating, solution casting, compression molding, injection molding, lamination, melt extrusion, blown film, extrusion coating, tandem extrusion coating, or any other suitable procedure. Preferably, the sheets are formed by a melt extrusion, melt coextrusion, melt extrusion coating, or tandem melt extrusion coating process.

In this connection, the terms “film” and “sheet”, as used herein, refer to substantially planar, continuous articles. The term “continuous”, as used in this context, means that the film or sheet has a length of at least about 3 m, at least about 10 m, at least about 50 m, at least about 100 m, or at least about 250 m. Moreover, the sheeting has an aspect ratio, that is, a ratio of length to width, of at least 5, at least 10, at least 25, at least 50, at least 75 or at least 100.

Moreover, the difference between a film and a sheet is the thickness; however, there is no industry standard for the precise thickness that distinguishes between a film and a sheet. As used herein, however, a film generally has a thickness of about 10 mils (0.254 mm), or less. A sheet generally has a thickness of greater than about 10 mils (0.254 mm). The descriptions herein pertain equally to films and to sheets, unless otherwise limited in specific instances. For convenience, however, only one of these terms may be used in a given context.

In addition, the sheets comprising the encapsulant composition may have a smooth or rough surface on one or both sides. Preferably, the sheets have rough surfaces on both sides to facilitate the deaeration during the lamination process. Rough surfaces may be produced by conventional processes such as mechanical embossing. For example, the as-extruded sheet may be passed over a specially prepared surface of a die roll positioned in close proximity to the exit of the die. This die roll imparts the desired surface characteristics to one side of the molten polymer. Thus, when the surface of such a textured roll has minute peaks and valleys, the still-impressionable polymer sheet cast on the textured roll will have a rough surface on the side that is in contact with the roll. The rough surface generally conforms respectively to the valleys and peaks of the roll surface. Textured rolls are described in, e.g., U.S. Pat. No. 4,035,549 and U.S. Patent Application Publication No. 2003/0124296.

Photovoltaic modules comprising a layer of the encapsulant composition described herein are resistant to potential-induced degradation (PID). Without wishing to be held to theory, it is believed that the encapsulant composition has a low permeability of ions, such as alkali metal cations and in particular sodium cations. Therefore, the ions are prevented from reaching the surface of the solar cell, where they may cause PID to occur.

Accordingly, further provided herein are photovoltaic modules comprising the encapsulant composition. Structures of photovoltaic modules that may suitably include the encapsulant composition include, without limitation, the structures that are described in detail in U.S. Pat. No. 8,399,081, issued to Hayes et al. A layer of the encapsulant composition may be substituted for any polymeric layer described by Hayes et al. Preferably, a layer of the encapsulant composition described herein is substituted for any encapsulant layer described by Hayes et al., including front or sun-facing encapsulant layers and back or non-sun-facing encapsulant layers. More preferably, a layer of the encapsulant composition described herein is substituted for an encapsulant layer that is disposed between the solar cells and a sheet of sodium ion-containing glass. Still more preferably, a layer of the encapsulant composition described herein is substituted for an encapsulant layer that is disposed between the solar cells and a sheet of sodium ion-containing glass on the front or sun-facing side of the photovoltaic module.

Also preferably, a layer of the encapsulant composition described herein is used in conjunction with any encapsulant layer described by Hayes et al. More specifically, a preferred photovoltaic module has the structure glass/first encapsulant layer/second encapsulant layer/solar cell assembly/third encapsulant layer/glass, in which one of the first or second encapsulant layers comprises the E/VA/X copolymer described herein and the other of the first or second encapsulant layers may be any encapsulant layer described by Hayes et al. In this preferred photovoltaic module, the first and second encapsulant layers may be front or back encapsulant layers. Moreover, any photovoltaic module comprising an encapsulant layer that is disposed between the solar cell assembly and a sheet of sodium ion-containing glass is a preferred photovoltaic module, when the so-disposed encapsulant layer is substituted with a first and a second encapsulant layer in which one of the first or second encapsulant layers comprises the E/VA/X copolymer described herein and the other of the first or second encapsulant layers may be any encapsulant layer described by Hayes et al.

Photovoltaic modules also comprise solar cell assemblies. These assemblies comprise one or more solar cells. The two most common types of photovoltaic modules include wafer-based solar cells or thin film solar cells. Photovoltaic modules that include wafer-based solar cells generally have a structure that includes the following layers: glass/encapsulant/solar cell(s)/encapsulant/glass or glass/encapsulant/solar cell(s)/encapsulant/flexible backsheet. Thin film solar cells are an alternative to wafer-based solar cells.

The materials commonly used for such cells include amorphous silicon (a-Si), microcrystalline silicon (pc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, organic semiconductors, and the like. By way of example, thin film solar cells are described in U.S. Pat. Nos. 5,507,881; 5,512,107; 5,948,176; 5,994,163; 6,040,521; 6,123,824; 6,137,048; 6,288,325; 6,258,620; 6,613,603; and 6,784,301; and U.S. Patent Publication Nos. 20070298590; 20070281090; 20070240759; 20070232057; 20070238285; 20070227578; 20070209699; 20070079866; 20080223436; and 20080271675, for example.

A thin film solar cell assembly typically comprises a substrate. Multiple layers of light absorbing and semiconductor materials are deposited on the substrate. The substrate may be glass or a flexible film. The substrate may also be referred to as a superstrate in those modules in which it faces toward the incoming sunlight. The thin film solar cell assemblies may further comprise conductive coatings, such as transparent conductive oxides (TCO) or electrical wirings, which are generally deposited on the semiconductor materials. Similarly to the wafer-based solar cell assemblies, the thin film solar cell assembly may be sandwiched or laminated between polymeric encapsulant layers, and this structure in turn may be sandwiched or laminated between outer protective layers.

The thin film solar cell assembly may have only one surface, specifically the surface opposite from the substrate or superstrate, that is laminated to a polymeric encapsulant layer. In these solar cell modules, the encapsulant layer is most often in contact with and laminated to an outer protective layer. For example, the thin film solar cell module may have a lamination structure comprising, in order of position from the front or sun-facing side to the back or non-sun-facing side, (1) a thin film solar cell assembly having a superstrate on its front sun-facing side, (2) a polymeric back encapsulant layer, and (3) a back protective layer or “back sheet.” In this structure, the superstrate performs the functions of the front protective layer.

Alternatively, the thin film solar cell module may have a laminated structure comprising, in order of position from the front or sun-facing side to the back or non-sun-facing side, (1) a front protective layer or “front sheet,” (2) a polymeric front encapsulant sheet, and (3) a thin film solar cell assembly having a substrate on its back or non-sun-facing side. In this structure, the substrate also performs the functions of the back protective layer.

Suitable plastic film layers used for backsheets include, without limitation, polymers such as polyesters (e.g., poly(ethylene terephthalate) and poly(ethylene naphthalate)), polycarbonates, polyolefins (e.g., polypropylene, polyethylene, and cyclic polyolefins), norbornene polymers, polystyrenes (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetate, etc.), cellophanes, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers and the like) and combinations of two or more thereof. The plastic film may also be a bi-axially oriented polyester film (preferably poly(ethylene terephthalate) film) or a fluoropolymer film (e.g., Tedlar®, Tefzel®, and Teflon® films, from E. I. du Pont de Nemours and Company, Wilmington, Del. (DuPont)). Further the films used herein may be in the form of a multi-layer film, such as a fluoropolymer/polyester/fluoropolymer multilayer film (e.g., Tedlar®/PET/Tedlar® or TPT laminate film available from Isovolta AG., Austria or Madico, Woburn, Mass.). These same materials, when transparent, are also suitable for use in flexible frontsheets.

The term “glass”, as used herein, includes window glass, plate glass, silicate glass, sheet glass, low iron glass, tempered glass, tempered low iron glass, tempered CeO-free glass, float glass, colored glass, specialty glass (such as those containing ingredients to control solar heating), coated glass (such as those sputtered with metal compounds (e.g., silver or indium tin oxide) for solar control purposes), low E-glass, Toroglas™ glass (Saint-Gobain N. A. Inc., Trumbauersville, Pa.), Solexia™ glass (PPG Industries, Pittsburgh, Pa.) and Starphire™ glass (PPG Industries). These and other specialty glasses are described in U.S. Pat. Nos. 4,615,989; 5,173,212; 5,264,286; 6,150,028; 6,340,646; 6,461,736; and 6,468,934, for example.

Other materials, such as polymeric films, may be substituted for one or more of the glass layers in both types of photovoltaic module. The photovoltaic modules of the invention, however, preferably include at least one layer of glass. When the encapsulant composition described herein is used in an encapsulant layer, these photovoltaic modules provide significantly greater stability with respect to PID, when compared to photovoltaic modules that include conventional EVA encapsulants. The improvement in stability is greater in photovoltaic modules in which the photovoltaic module comprises glass. Preferably, the glass is not a low sodium or low alkali glass, such as the glasses described in Intl. Patent Appln. Publn. No. WO2013/020128.

When the photovoltaic module comprises more than one encapsulant layer, the additional encapsulant layer(s) may comprise the encapsulant composition as described herein. Alternatively, the additional encapsulant layer(s) may comprise other polymeric materials, such as acid copolymers, ionomers of acid copolymers, ethylene/vinyl acetate copolymers, poly(vinyl acetals) (including acoustic grade poly(vinyl acetals)), polyurethanes, poly(vinyl chlorides), polyethylenes (e.g., linear low density polyethylenes), polyolefin block copolymer elastomers, copolymers of α-olefins and α,β-ethylenically unsaturated carboxylic acid esters) (e.g., ethylene methyl acrylate copolymers and ethylene butyl acrylate copolymers), silicone elastomers, epoxy resins, any encapsulant layer described by Hayes et al., and combinations of two or more of these materials.

Each encapsulant layer in the photovoltaic module has a thickness that may independently range from about 5 to about 40 mils (about 0.125 to about 1 mm), or about 2 to about 30 mils (about 0.250 to about 0.625 mm), or about 15 to about 20 mils (about 0.381 to about 0.505 mm). When the encapsulant layer is in multilayer form, the total thickness of the multilayer encapsulant falls within the ranges set forth above. Additionally, the photovoltaic modules described herein may have more than one encapsulant layer, for example a front encapsulant layer (in front of the solar cell) and a back encapsulant layer (behind the solar cell). Each of these encapsulant layers has a total thickness as set forth above.

Photovoltaic modules comprising the encapsulant composition may be made by any suitable process. Photovoltaic modules are most often made by vacuum lamination processes, such as those described in U.S. Pat. No. 5,593,532. Alternatively, photovoltaic modules may be made by autoclave lamination processes, such as those described with respect to glass laminates in U.S. Pat. No. 7,763,360 and in U.S. Patent Publication No. 2007/0228341. Non-autoclave lamination processes may also be used, however. Some examples of suitable non-autoclave lamination processes are also described in U.S. Pat. Nos. 7,763,360 and 8,637,150.

It is believed that one of ordinary skill in the art will be able to make any adjustments to the lamination process that may be required. For example, if the melt index of the encapsulant composition described herein is increased relative to that of a conventional encapsulant layer, reasonable adjustments to the process include decreasing the lamination temperature or the cycle time.

The following examples are provided to describe the invention in further detail. These examples, which set forth specific embodiments and a preferred mode presently contemplated for carrying out the invention, are intended to illustrate and not to limit the invention.

### Examples

### Materials and Methods

The following materials were used throughout the Examples, unless otherwise specified:
Annealed Float Glass—AGC Solite 145×155×3.2 mm, AGC Flat Glass North America, Alpharetta, Ga.
Back Sheets—Dun-Solar 1200TPT, Dunmore Corp., Bristol, Pa.
Solar Cells—Motech monocrystalline XS125-165R, Motech Industries, Tainan City, Taiwan
Wires, tabbing ribbon, busbars—Wuxi Sveck Technology, Wuxi, China
   Composition—62% tin, 36% lead, 2% silver
   Tabbing ribbon—0.16×2 mm
   Busbars—0.2×5 mm
Junction Box—Renhe Solar, Model No. PV-RH06-60, Renhe Solar, Zhejiang, China
Encapsulants
   EVA—STR Photocap 15295P, STR Holdings, Enfield, Conn.
   Commercial EVA #1—STR Photocap 15295, STR Holdings, Enfield, Conn.
   Commercial EVA #2—STR Photocap 15505, STR Holdings, Enfield, Conn.
   Commercial EVA #3—STR Photocap 15585, STR Holdings, Enfield, Conn.
   Elvax® 4260 and 4355 EVA Resins—DuPont
   Ionomer—Surlyn® 1702—DuPont

The photovoltaic modules were formed by lamination according to the following method. Annealed float glass (AGC Solite 145×155×3.2 mm, AGC Flat Glass North America, Alpharetta, Ga.) was rinsed with de-ionized water and dried.

The following module construction was made: glass/front encapsulant/one solar cell/EVA/backsheet. The front encapsulants that were used are described in the Examples. The solar cells (XS125-165R, Motech Industries, Inc., Tainan City, Taiwan) were mono-crystalline and tabbed with 0.16×2 mm ribbon (Wuxi Sveck Technology, Wuxi, China). The 0.2×5 mm busbars (Wuxi Sveck Technology, Wuxi, China) were electrically isolated with the Dunsolar 1200TPT backsheet (Dunmore Corporation, Bristol, Pa.).

The vacuum-lamination cycle was at set temperature of 150° C. with an 18 minute processing time in which the vacuum time was 4 minutes and the press time was 13 minutes at a constant pressure of 1000 mbar. The vacuum laminator was a Meier Icolam Model 2515 (NPC-Meier GMBH, Bocholt, Germany). The mini-module was removed from the vacuum laminator and allowed to cool to ambient temperature. The busbars were soldered to the junction box, which was attached to the module with a sealant.

Photovoltaic modules were tested for PID according to the following method. The modules were taped on all four edges of the cover glass with 3M 1-inch aluminum-based tape (3M Company, Saint Paul, Minn.). The front surface of the modules was completely covered with untreated aluminum foil. The aluminum foil-covered modules were held at 60° C. and 85% relative humidity in an environmental chamber (Model SE-3000-4, Thermotron Industries, Holland, Mich.) for up to 96 hours while a voltage potential of −1 kV was applied between the aluminum foil and the solar cells for 24 or 96 h (shown in the examples as “24 h PID test” or “96 h PID test”. Testing was also done for up to 192 hours as shown in FIG. 2.

### Experiments:

The modules were constructed in the following order: a cover glass, front encapsulant, one solar cell tabbed with interconnect ribbons, a commercial EVA encapsulant, and a backsheet. The front encapsulant for each module is described in Table 1 below. Table 1 summarizes the power retained after module exposure to −1000V and 60° C./85% relative humidity (RH), when the modules were covered with aluminum foil. Comparative Examples CE1 to CE6 as well as Examples E1 to E6 had monolayer front encapsulants, while Examples E7 and E8 had bi-layer front encapsulants. E7 was constructed so that the E/VA/X copolymer encapsulant was adjacent to the cover glass, and E8 was constructed so that the commercial EVA encapsulant was adjacent to the cover glass.

TABLE 1

| | | | | % Power after |
|---|---|---|---|---|
| Example No. | | Front Encapsulant adjacent to Cover Glass | % Power after 24 h | 96 h |
| CE1 | Sample 1 | E/28% VA, 18 mil thick | 84% | 60% |
| | Sample 2 | E/28% VA, 18 mil thick | 89% | 57% |
| CE2 | Sample 1 | Commercial EVA encapsulant #1, 18 mil thick | 2% | — |
| | Sample 2 | Commercial EVA encapsulant #1, 18 mil thick | 5% | — |
| | Sample 3 | Commercial EVA encapsulant #1, 18 mil thick | 2% | — |
| | Sample 4 | Commercial EVA encapsulant #1, 18 mil thick | 6% | — |
| | Sample 5 | Commercial EVA encapsulant #1, 18 mil thick | 4% | — |
| | Sample 6 | Commercial EVA encapsulant #1, 18 mil thick | 10% | — |
| | Sample 7 | Commercial EVA encapsulant #1, 18 mil thick | 5% | — |
| CE3 | | Commercial EVA encapsulant #2, 18 mil thick | — | 0.10% |
| CE4 | | Commercial EVA encapsulant #3, 18 mil thick | — | 73% |
| CE5 | | 7.5% (E/15% MAA) and 92.5% (E/28% VA) blend, 18 mil thick | — | 75% |
| CE6 | | 10% (E/15% MAA/Zn) and 90% (E/28% VA) blend, 18 mil thick | | 44% |
| E1 | | 10% (E/28% VA/% 1MAA) and 90% (E/28% VA) blend, 18 mil thick | — | 92% |
| E2 | | 20% (E/28% VA/% 1MAA) and 80% (E/28% VA) blend, 18 mil thick | — | 98% |
| E3 | | 30% (E/28% VA/% 1MAA) and 70% (E/28% VA) blend, 18 mil thick | — | 98% |
| E4 | | 40% (E/28% VA/% 1MAA) and 60% (E/28% VA) blend, 18 mil thick | — | 93% |
| E5 | Sample 1 | E/28% VA/1% MAA, 18 mil thick | — | 97% |
| | Sample 2 | E/28% VA/1% MAA, 18 mil thick | — | 100% |
| E6 | | E/25% VA/1% MAA, 18 mil thick | — | 99% |
| E7 | | 8 mil E/28% VA/1% MAA and 18 mil E/28% VA bilayer | 97% | 91% |
| E8 | | 18 mil E/28% VA and 8 mil E/28% VA/1% MAA bilayer | 96% | 99% |

After the test period of 24 or 96 h, the modules were monitored by electroluminescence and by power measurements. Electroluminescence (EL) was measured with an Oasis Op-tection instrument-Module D (Op-tection GMBH, Heinsberg, Germany). The power output of the modules was measured with a Spire SPI-SUN Simulator 4600SLP (Spire Group LLC, Ridgefield, Conn.) with an AMI 1.5 light source according to IEC 16215.

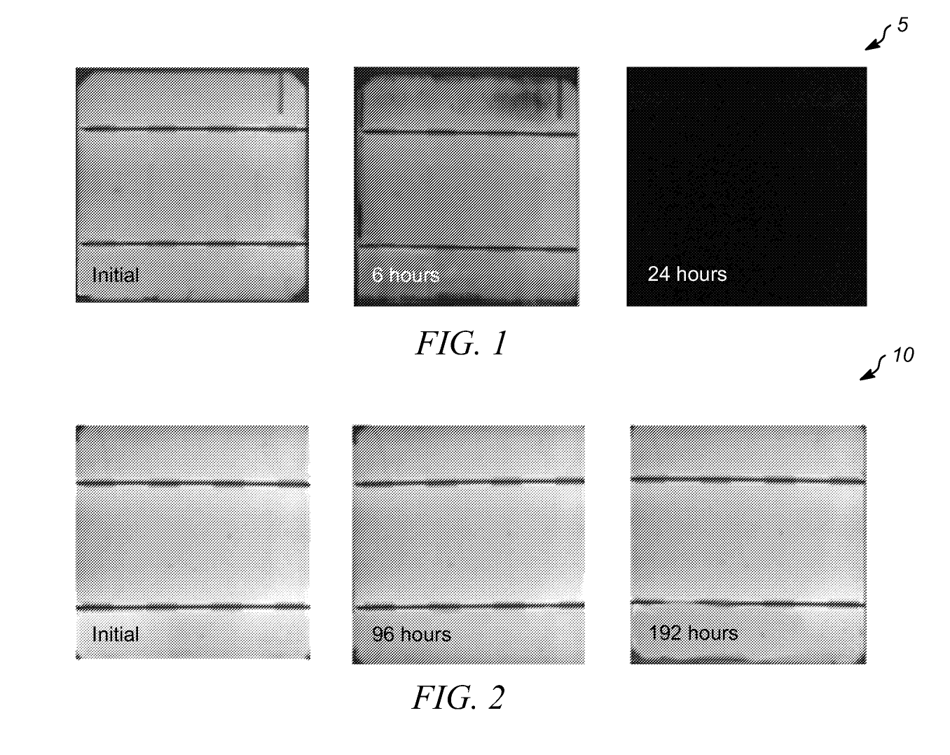

The solar modules made with commercially available EVA copolymer encapsulant did not produce an electroluminescence image, were destroyed by PID test procedure and lost more than 90% of their power within 24 hours. The degradation of the Comparative Example module CE2 as a result of −1000V and 60° C./85% RH testing with foil at 6 and 24 hours is shown in the electroluminescence photographs (5) in FIG. 1. The electroluminescence images of the E/VA/MAA terpolymer (Example E5) show that the power was above 95% of the initial power output after 96 hours and even after 192 hours (tested in the same fashion), as shown in the electroluminescence photographs (10) in FIG. 2.

These results demonstrate that photovoltaic modules having E/VA/X encapsulants (Examples E5 and E6) exhibited no measurable reduction in PID over the test period. Blends of E/VA/MAA terpolymer and EVA copolymer retained power above 90% (Examples E1 through E4). Examples E1 to E6 showed that 100% E/VA/MAA terpolymers (E5 and E6) and their blends (Examples E1 to E4) are surprisingly better than a copolymer blend of EVA and EMAA (CE5) or a blend of EVA and an ionomer of EMAA (CE6). In contrast, photovoltaic modules having conventional EVA encapsulants (Comparative Examples CE1 and CE2) lost 90% or more of the modules' initial power by PID within 24 hours under the test conditions.

Volume resistivity is the resistance to the flow of electric current through the body of an insulating encapsulant. In theory, the higher the volume resistivity of the encapsulant, the less conductive the material is, and the lower the leakage current of the module. Volume resistivity of the encapsulant materials can be measured according to ASTM Method D257-07 at various temperatures.

Volume resistivity measurements of various encapsulants show that the correlation of volume resistivity to power output of the module is not straightforward. Thus, it is surprising that E/VA/X copolymers provide protection against potential-induced degradation even though their volume resistivity is similar to that of the commercial EVA encapsulants, as shown in Table 2 below. Also, the results shown in Table 2 are surprising in light of the descriptions in U.S. Pat. No. 8,188,363, which discusses the need for the presence of an electrical insulator layer to provide protection against potential-induced degradation and does not consider EVA-type encapsulants as insulators.

TABLE 2

| | | | | E3 | |
|---|---|---|---|---|---|
| | CE2 | CE4 | | 30% E/VA/X | |
| | Commercial | Commercial | | copolymer - | |
| | EVA | EVA | | 70% | E5 |
| | encapsulant | encapsulant | CE1 | (E/28% VA) | E/VA/X |
| | #1 | #3 | E/28% VA | blend | copolymer |
| Volume | 1E+14 | 2E+15 | 9E+14 | 2E+14 | 1E+15 |
| Resistivity at | | | | | |
| 23 C./50% RH | | | | | |
| Volume Resistivity | 9E+12 | 2E+14 | 8E+13 | 5E+13 | 5E+13 |
| at 50% C/50% RH | | | | | |
| Power after PID | <10% | 73% | 57% & 60% | 98% | 97% & 100% |
| 96 h Test | | | | | |

While certain of the preferred embodiments of this invention have been described and specifically exemplified above, it is not intended that the invention be limited to such embodiments. Various modifications may be made without departing from the scope and spirit of the invention, as set forth in the following claims.

What is claimed is:

1. A photovoltaic module comprising an encapsulant layer and a solar cell assembly, said encapsulant layer comprising an encapsulant composition, and said encapsulant composition comprising a copolymer or an ionomer that is a neutralized product of the copolymer; wherein the copolymer comprises copolymerized residues of ethylene, copolymerized residues of vinyl acetate and copolymerized residues of a third comonomer; and wherein the third comonomer is selected from the group consisting of carbon monoxide, an α,β-ethylenically unsaturated carboxylic acid having from 3 to 8 carbon atoms, maleic anhydride and maleic anhydride mono-methyl ester (MAME).

2. The photovoltaic module of claim 1, wherein the copolymer comprises about 15 wt % to about 35 wt % of copolymerized residues of vinyl acetate and about 0.1 wt % to about 10 wt % of copolymerized residues of the third comonomer, and
wherein the sum of the weight percentages of the copolymerized residues in the copolymer is 100 wt %.

3. The photovoltaic module of claim 2, wherein the copolymer comprises about 0.1 wt % to about 5 wt % of copolymerized residues of the third comonomer.

4. The photovoltaic module of claim 2, wherein the copolymer comprises about 0.1 wt % to about 2 wt % of copolymerized residues of the third comonomer.

5. The photovoltaic module of claim 1, wherein the encapsulant composition comprises one or more other polymers.

6. The photovoltaic module of claim 5, wherein the encapsulant composition comprises 0 to about 98 wt % of one or more other polymers and about 2 wt % to about 100 wt % of the copolymer, based on the total weight of the copolymer and of the one or more other polymers.

7. The photovoltaic module of claim 5, wherein the encapsulant composition comprises 0 to about 95 wt % of one or more other polymers and about 5 wt % to about 100 wt % of the copolymer, based on the total weight of the copolymer and of the one or more other polymers.

8. The photovoltaic module of claim 5, wherein the encapsulant composition comprises 0 to about 90 wt % of one or more other polymers and about 10 wt % to about 100 wt % of the copolymer, based on the total weight of the copolymer and of the one or more other polymers.

9. The photovoltaic module of claim 1, further comprising one or more glass layers, one or more flexible back sheet layers, or a second encapsulant layer that may be the same as or different from the encapsulant layer.

10. The photovoltaic module of claim 9 that has a structure selected from the group consisting of: glass/encapsulant/solar cell assembly/encapsulant layer/glass; glass/encapsulant/solar cell assembly/encapsulant/flexible backsheet; glass/encapsulant/solar cell assembly/glass; and glass/encapsulant/solar cell assembly/flexible backsheet.

11. The photovoltaic module of claim 1, wherein the solar cell assembly comprises a thin film solar cell.

12. The photovoltaic module of claim 1, wherein the encapsulant layer is in multilayer form.

13. An encapsulant composition for use in a photovoltaic module, said encapsulant composition comprising a copolymer of ethylene, vinyl acetate and a third comonomer or an ionomer that is the neutralized product of the copolymer; wherein said third comonomer is selected from the group consisting of carbon monoxide, an α,β-ethylenically unsaturated carboxylic acid having from 3 to 8 carbon atoms, maleic anhydride and maleic anhydride mono-methyl ester (MAME).

14. A method of reducing the potential-induced degradation of a photovoltaic module, said method comprising the steps of:
providing a solar cell assembly, a glass layer, and an encapsulant layer comprising the encapsulant composition of claim 13;
fabricating a photovoltaic module comprising the structure glass layer/encapsulant layer/solar cell assembly;
operating the photovoltaic module; and
observing the current generated by the photovoltaic module as a function of time.
